(19) United States
(12) Patent Application Publication
(10) Pub. No.: US 2015/0053993 A1
(43) Pub. Date: Feb. 26, 2015

(54) SEMICONDUCTOR LIGHT EMITTING DEVICE

(71) Applicant: Kabushiki Kaisha Toshiba, Tokyo (JP)

(72) Inventor: Reiji Ono, Kanagawa-ken (JP)

(73) Assignee: KABUSHIKI KAISHA TOSHIBA, Tokyo (JP)

(21) Appl. No.: 14/158,360

(22) Filed: Jan. 17, 2014

(30) Foreign Application Priority Data
Aug. 23, 2013 (JP) 2013-173010

(51) Int. Cl. H01L 33/32

(52) U.S. Cl. CPC H01L 33/32
USPC 257/76; 257/98

(57) ABSTRACT

A semiconductor light-emitting device includes a substrate, a semiconductor light-emitting element, and a transparent resin. The substrate is configured to have an opening portion. The opening portion includes a lower portion and an upper portion narrower than the lower portion. The semiconductor light-emitting element is placed in a central portion of the substrate. The transparent resin covers the semiconductor light-emitting element and is provided to the opening portion.

### CROSS REFERENCE TO RELATED APPLICATION

This application is based upon and claims the benefit of priority from the prior Japanese Patent Application No. 2013-173010, filed on Aug. 23, 2013, the entire contents of which are incorporated herein by reference.

### FIELD

Embodiments described herein generally relate to a semiconductor light-emitting device.

### BACKGROUND

In the background art, semiconductor light-emitting devices are known to emit white light for lighting. Semiconductor light-emitting elements are normally placed on a ceramic substrate in order to raise heat dissipation.

Fluorescent material is applied to a semiconductor light-emitting element. The semiconductor light-emitting element is covered with a transparent dome-shaped resin.

The semiconductor light-emitting element produces much heat by energization. A thermal expansion coefficient of the transparent resin is larger than the thermal expansion coefficient of the ceramic substrate. As a result, stress is generated at an interface between the transparent resin and the ceramic substrate in accordance with a difference between the thermal expansion coefficients thereof.

The stress often exceeds an adhesion between the ceramic substrate and the transparent resin to detach the transparent resin from the ceramic substrate, thereby forming a crevice therebetween.

As a result, moisture or a contaminant invades from the crevice, and can deteriorate reliability of a semiconductor light-emitting device.

### BRIEF DESCRIPTION OF THE DRAWINGS

The accompanying drawings, which are incorporated in and constitute a part of this specification, illustrate embodiments of the invention and together with the description, serve to explain the principles of the invention.

FIGS. 1A and 1B are a plan view and a sectional view, respectively, showing a semiconductor light-emitting device according to an embodiment.

FIG. 1B shows a cross section of the device, the section cut and viewed along the line A-A.

FIGS. 2A and 2B are diagrams showing the semiconductor light-emitting device according to the embodiment in comparison with a semiconductor light-emitting device of a comparative example.

FIGS. 3A to 3C and FIGS. 4A and 4B are sectional views sequentially showing steps of manufacturing the semiconductor light-emitting device according to the embodiment.

FIGS. 5A and 5B and FIGS. 6A and 6B are plan views showing another substrate of the semiconductor light-emitting device according to the embodiment.

FIG. 7 is a sectional view showing another semiconductor light-emitting device according to the embodiment.

FIG. 8 is a sectional view showing another semiconductor light-emitting device according to the embodiment.

FIG. 9 is a sectional view showing another semiconductor light-emitting device according to the embodiment.

FIG. 10 is a sectional view showing another semiconductor light-emitting device according to the embodiment.

FIG. 11 is a sectional view showing another semiconductor light-emitting device according to the embodiment.

### DETAILED DESCRIPTION

A semiconductor light-emitting device includes a substrate, a semiconductor light-emitting element, and a transparent resin. The substrate is configured to have an opening portion. The opening portion includes a lower portion and an upper portion narrower than the lower portion. The semiconductor light-emitting element is placed in a central portion of the substrate. The transparent resin covers the semiconductor light-emitting element and is provided to the opening portion.

An embodiment will be described with reference to the drawings. Wherever possible, the same reference numerals will be used to denote the same or like portions throughout the drawings. The same description will not be repeated in the detailed description.

### Embodiment

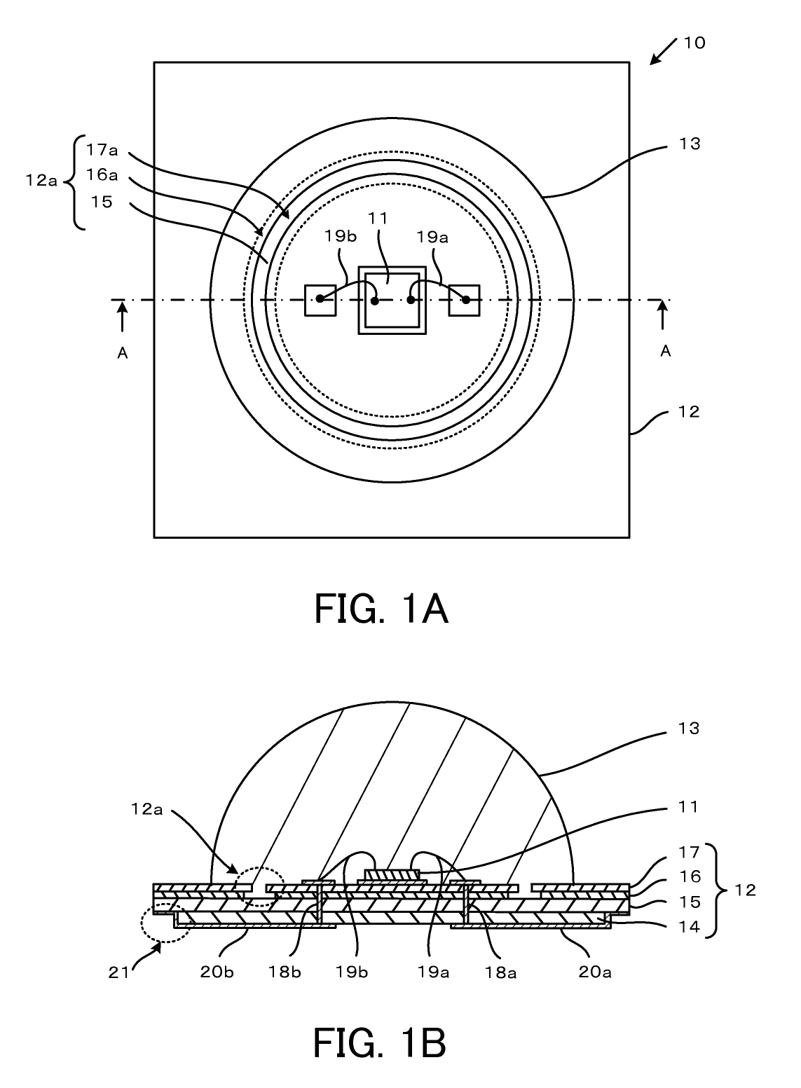

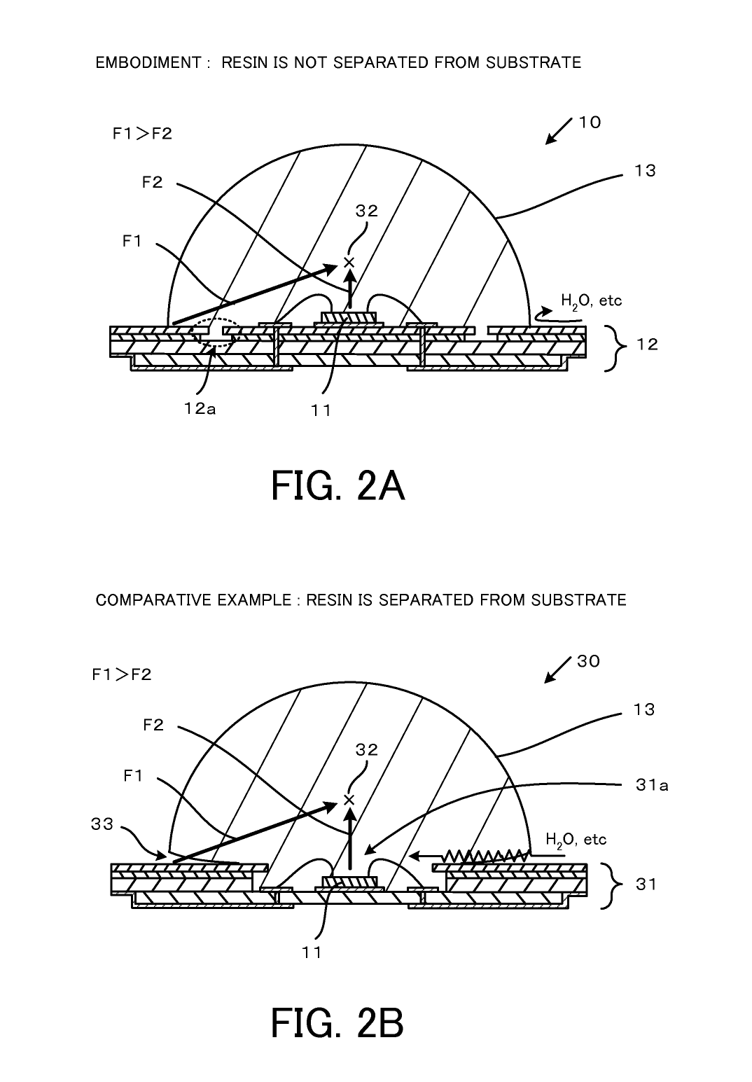

A semiconductor light-emitting device in accordance with an embodiment will be described with reference to FIGS. 1A, 1B, 2A and 2B. FIGS. 1A and 1B are a plan view and a sectional view, respectively, showing a semiconductor light-emitting device of the embodiment. FIG. 1B shows a cross section of the device, the section cut and viewed along the line A-A.

A fluorescent material is applied to a nitride semiconductor light-emitting element of this embodiment. The fluorescent material absorbs blue light from the nitride semiconductor light-emitting element to emit yellow light. The nitride semiconductor light-emitting element includes a transparent resin molded into a dome thereon.

As shown in FIG. 1, a semiconductor light-emitting device 10 of the embodiment includes a semiconductor light-emitting element 11 that is placed on a central portion of a substrate 12. The substrate 12 has an opening portion 12a, which has a lower portion and an upper portion narrower than the lower portion in the opening portion 12a so as to surround a semiconductor light-emitting element 11 at an outer circumference of the substrate 12.

A dome-shaped transparent resin 13 is provided on the substrate 12 so as to cover the semiconductor light-emitting element 11 and be provided to the opening portion 12a with a portion of the transparent resin 13.

The substrate 12 is a stacked substrate where substrates 14, 15, 16, 17 are sequentially stacked. The substrate 17 is a top substrate (a first substrate). The substrate 16 is an intermediate substrate (a second substrate) just below the top substrate. The substrate 14 is a bottom substrate (a third substrate). The substrate 15 is an intermediate substrate just above the bottom substrate. Examples of the substrates 14, 15, 16, 17 include a square ceramic substrate with a size of 3 to 5 mm.

The semiconductor light-emitting element 11 is a GaN-based semiconductor light-emitting element with a size of 1 to 2 mm, which emits blue light with a peak wavelength of 400 to 480 nm. The semiconductor light-emitting element 11 stacks an n-type GaN clad layer, a semiconductor light-emitting layer, a p-type GaN clad layer, and a p-type contact layer on a sapphire substrate in order. The semiconductor light-emitting layer includes a multiquantum well structure including alternating layers of InGaN well layers and GaN barrier layers. A p-electrode (not shown) is provided onto the p-type GaN contact layer. An n-electrode (not shown) is provided onto a notch (not shown) that exposes the n-type GaN clad layer.

The semiconductor light-emitting element 11 is bonded to the substrate 17, i.e., a top layer of the substrate 12, e.g., with a silver paste. A fluorescent material (not shown) is provided between the semiconductor light-emitting element 11 and the resin 13. The fluorescent material absorbs first light from the semiconductor light-emitting element 11 to emit second light which has a peak wavelength longer than that of the first light. The fluorescent material is provided, for example, on an upper surface of the semiconductor light-emitting element 11.

The substrate 12 includes the opening portion 12a, which surrounds the semiconductor light-emitting element 11 on the substrate 12. The opening portion 12a has a lower portion and an upper portion narrower than the lower portion. The top substrate 17 includes an upper opening portion 17a (a first opening portion) and the substrate 16 just under the top substrate 17 includes a lower opening portion 16a (a second opening portion). The opening portion 17a has a ring shape. The opening portion 16a has a concentric ring shape to the ring shape of the opening portion 17a.

Edges of the upper opening portion 17a of the substrate 17 protrude like a visor over the lower opening portion 16a toward a center line of the upper opening portion 17a. The opening portion 12a is made up of an upper surface of the substrate 15 exposed to the lower opening portion 16a, inside walls of the lower opening 16a, and the edges of the upper opening 17a protruding like a visor over the lower opening 16a. As a result, the opening portion 12a has the lower portion and the upper portion narrower than the lower portion.

Vias 18a, 18b passing through the substrate 12 are provided between the semiconductor light-emitting element 11 and the opening portion 12a. First end of the via 18a is electrically connected to the p-electrode of the semiconductor light-emitting element 11 through a wire 19a. First end of the via 18b is electrically connected to an n-electrode of the semiconductor light-emitting element 11 through a wire 19b.

Second end of the via 18a is electrically connected to an electrode 20a provided to the bottom substrate 14. Second end of the via 18b is electrically connected to an electrode 20b provided to the bottom substrate 14. The electrode 20a is an anode and the electrode 20b is a cathode.

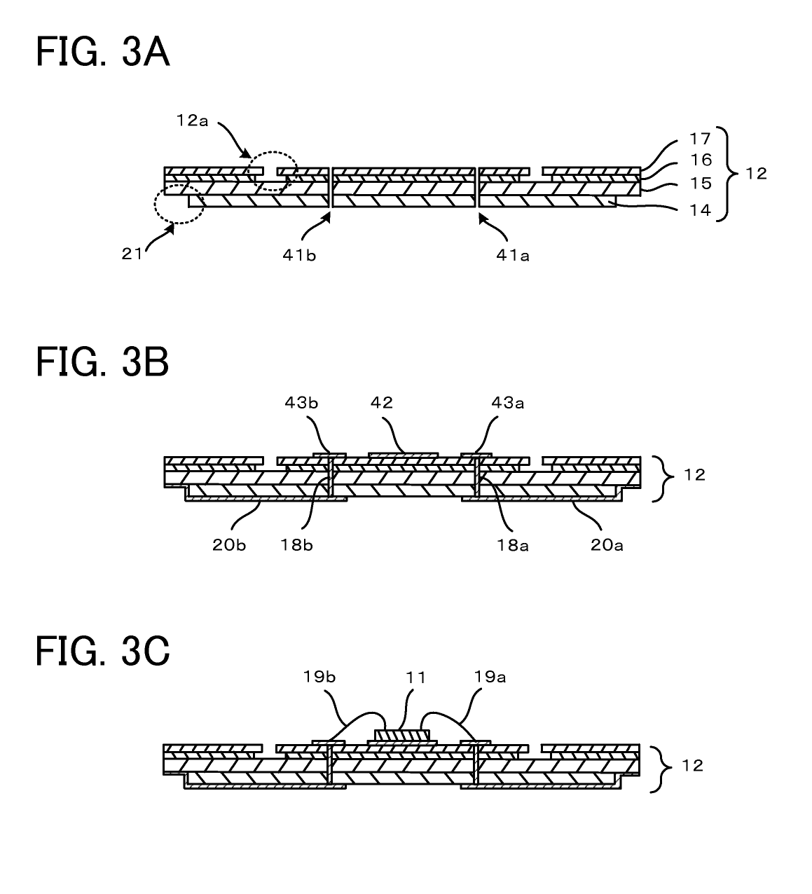

The bottom substrate 14 is smaller than the substrate 15 right thereon in size. As shown in FIG. 3A, an edge of the substrate 14 and an outermost edge of the substrate 15 make up a level difference 21. The electrode 20a extends from the second end of the via 18a to an outer edge of the substrate 15 while covering the level difference 21. In a similar way, the electrode 20b extends from the second end of the via 18b to the other edge of the substrate 15 while covering the level difference 21. The level difference 21 is provided such that a solder fillet is sufficiently formed to solder the semiconductor light-emitting device 10 to a printed circuit board, etc.

The resin 13 is a hemisphere-shaped silicone resin, for example. The semiconductor light-emitting element 11 is arranged substantially at the center of the hemisphere. The semiconductor light-emitting element 11 is approximated by a point light source. Since light emitted from the semiconductor light-emitting element 11 perpendicularly enters the hemisphere, total reflections does not occur at an interface between the hemisphere and the air.

In the embodiment, the opening portion 12a is provided so as to surround the semiconductor light-emitting element 11 on the substrate 12, and the upper portion of the opening portion 12a is narrower than the lower portion of the opening portion 12a. Thus, the opening portion 12a is operable as an anchor to prevent the resin 13 from being separated from the substrate 12.

FIGS. 2A and 2B are diagrams showing the semiconductor light-emitting device 10 of the embodiment in comparison with a semiconductor light-emitting device 30 of a comparative example. The comparative example will be firstly described. As shown in FIG. 2B, the semiconductor light-emitting device 30 of the comparative example has a substrate 31 having an opening portion 31a, which has a lower portion and an upper portion narrower than the lower portion in the center of the substrate 31. The semiconductor light-emitting element 11 is placed in the center of the opening portion 31a. The resin 13 covers the semiconductor light-emitting element 11, and the opening portion 31a is filled with the resin 13. The substrate 31 has the same substance as the substrate 12.

The semiconductor light-emitting element 11 is lighted to produce heat due to Joule loss of energization, which raises the temperatures of the resin 13 and the substrate 31. The resin 13 and the substrate 31 expand in accordance with the respective thermal expansion coefficients.

The thermal expansion coefficient of the resin 13 is normally larger than the thermal expansion coefficient of the substrate 31 approximately double figures. The thermal expansion coefficient of silicone resin is about 4×10⁻⁴/K. The thermal expansion coefficient of a ceramic substrate, e.g., of alumina is about 7×10⁻⁶/K. Stress is generated at an interface between the resin 13 and the substrate 31 depending on the difference between the thermal expansion coefficients of the resin 13 and the substrate 31.

Once the semiconductor light-emitting element 11 is switched off, the heat generation of the semiconductor light-emitting element 11 stops, and subsequently the temperatures of the resin 13 and the substrate 31 starts to decrease. The resin 13 and the substrate 31 start to contract in accordance with the respective thermal coefficients. The resin 13 contracts toward the gravity center 32 thereof. The contractile force, which is directed in the direction of the gravity center 32, acts on the resin 13 so as to detach the resin 13 from the substrate 31.

The contractile force acting on the resin 13 depends on the distance from the gravity center 32. A contractile force F1 from an outer circumference of the resin 13 to the gravity center 32 is larger than a contractile force F2 from the central area of the resin 13 to the gravity center 32. The contractile force F1 or F2 exceeds adhesion power between the resin 13 and the substrate 31 to detach the resin 13 from the substrate 31. Since the contractile force F1 is larger than the contractile force F2, the outer circumference can be detached from the substrate 31 earlier than the central area.

In the semiconductor light-emitting device 30 of the comparative example, the opening portion 31a has the lower portion and the upper portion narrower than the lower portion in the center of the substrate 31. Accordingly, the opening portion 31a can operate as an anchor to increase the adhesion power between the resin 13 and the substrate 31 in the center of the substrate 31. Such an opening portion, which has a lower portion and an upper portion narrower than the lower portion, is not provided to the outer circumference of the substrate 31. Accordingly, the adhesion power between the resin 13 and the substrate 31 is not increased in the outer circumference of the substrate 31.

When the contractile force F1 exceeds the adhesion power between the resin 13 and the substrate 31, the resin 13 is detached from the outer circumference of the substrate 31 so that a crevice 33 is produced. Once moisture, a sulfide, etc. intrude from the crevice 33, problems occur, which include deterioration of metal electrodes and a reduction in light-extraction efficiency.

Since the opening portion 31a is close to the semiconductor light-emitting element 11, the temperatures of the resin 13 and the substrate 31 rise in the opening portion 31a more than in the outer circumference. Such temperature rises depend on the distance between the opening portion 31a and the semiconductor light-emitting element 11, and on heat conductivities of the substrate 31 and the resin 31. Accumulation of thermal fatigue due to switching the semiconductor light-emitting device 30 on and off gives rise to problems including a gradual reduction in the adhesion power between the resin 13 and the substrate 31 in the opening portion 31a.

In contrast, the semiconductor light-emitting device 10 of the embodiment, as shown in FIG. 2A, includes the opening portion 12a in the outer circumference of the substrate 12. Since the opening portion 12a has the lower portion and the upper portion narrower than the lower portion so as to be operable as an anchor, the opening portion 12a increases the adhesion power between the resin 13 and the substrate 12. As a result, the opening portion 12a can prevent the resin 13 from being detached from the substrate 12.

Furthermore, since the opening portion 12a is separated from the semiconductor light-emitting element 11, a small rise in the temperatures of the resin 13 and the substrate 12 occurs at the opening portion 12a as a result of heat from the semiconductor light-emitting element 11. Accordingly, it is enabled to prevent the adhesion power between the resin 13 and the substrate 12 from gradually decreasing as a result of accumulation of thermal fatigue due to switching the semiconductor light-emitting device 10 on and off.

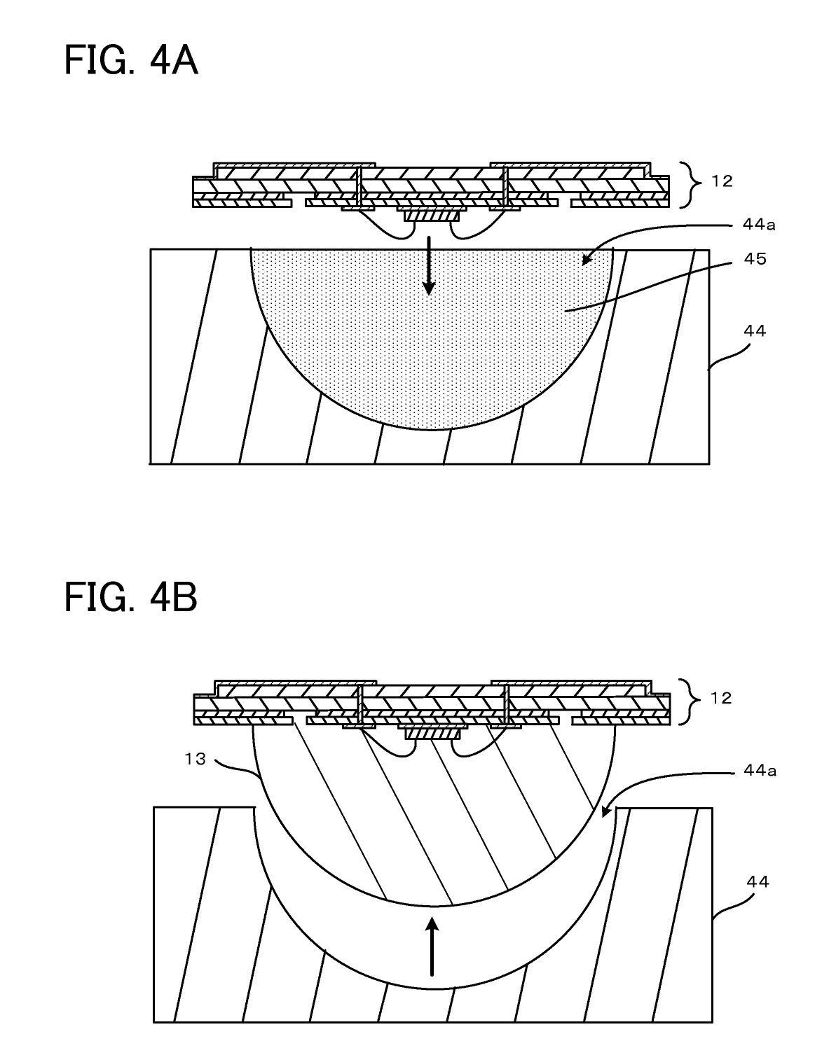

A method of manufacturing the semiconductor light-emitting device 10 of the embodiment will be described below. FIGS. 3A to 3C and FIGS. 4A and 4B are sectional views sequentially showing steps of manufacturing the semiconductor light-emitting device 10.

As shown in FIG. 3A, the substrates 14 to 17 are prepared beforehand. The substrates 14 and 15 are rectangular plates. A rectangular plate as the substrate 16 has a large center hole to form the ring-shaped opening portion 16a. The substrate 17 will be described in the same way. The substrates 14 to 17 each have through-holes that are to form vias 18a, 18b.

The substrates 14 to 17 are sequentially bonded to each other with an adhesive agent while the respective through-holes for the vias 18a, 18b of the substrates 14 to 17 are aligned with each other. Thus, the obtained substrate 12 includes the through-holes 41a and 41b for the vias 18a, 18b, the opening portion 12a having the lower portion and the upper portion narrower the lower portion, and the level difference 21.

As shown in FIG. 3B, nickel/gold is plated to the substrate 12, for example. As a result, the vias 18a, 18b, electrodes 20a, 20b, a die pad 42 to place the semiconductor light-emitting element 11, and bonding pads 43a, 43b to bond wires 19a, 19b are formed.

As shown in FIG. 3C, the semiconductor light-emitting element 11 is bonded to the die pad 42 with a silver paste. The end of the wire 19a is bonded to the p-electrode of the semiconductor light-emitting element 11 and the other end of the wire 19a is bonded to the bonding pad 43a. The end of the wire 19b is bonded to the n-electrode of the semiconductor light-emitting element 11 and the other end of the wire 19b is bonded to the bonding pad 43b.

As shown in FIG. 4A, a metallic mold 44 is prepared, which has a dome-shaped concave portion 44a capable of storing the semiconductor light-emitting element 11. A liquid resin is injected into the concave portion 44a of the metallic mold 44 with a dispenser (not shown). The semiconductor light-emitting element 11 is reversed to be placed into the concave portion 44a of the metallic mold 44. Subsequently, the resin 45 is cured.

As shown in FIG. 4B, the resin 13, which has been cured, is pulled out of the metallic mold 44. As a result, the obtained semiconductor light-emitting element 11 is covered with the dome-shaped resin 13 filling the opening portion 12a therewith.

As described above, the semiconductor light-emitting device 10 of the embodiment has the semiconductor light-emitting element 11, which is placed on the center of the substrate 12. The substrate 12 has the opening portion 12a with the lower portion and the upper portion narrower than the lower portion. The semiconductor light-emitting element 11 is covered with the transparent dome-shaped resin 13, and the opening portion 12a is filled with the transparent dome-shaped resin 13. As a result, the opening portion 12a serves as an anchor that increases the adhesion power between the resin 13 and the substrate 12. Thus, the obtained semiconductor light-emitting device enables it to prevent the resin from being detached from the substrate.

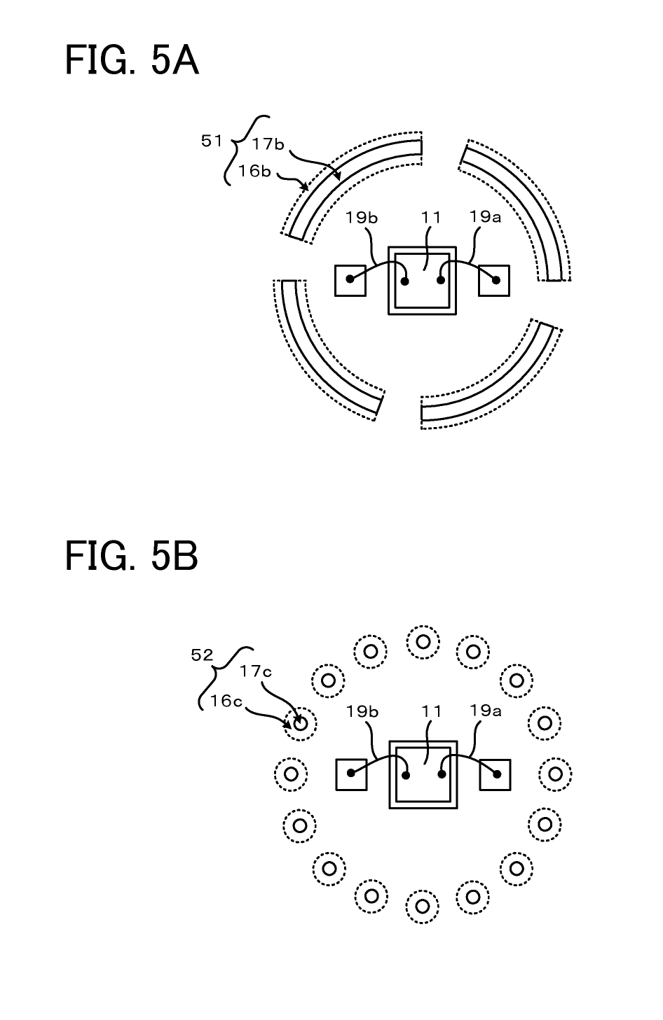

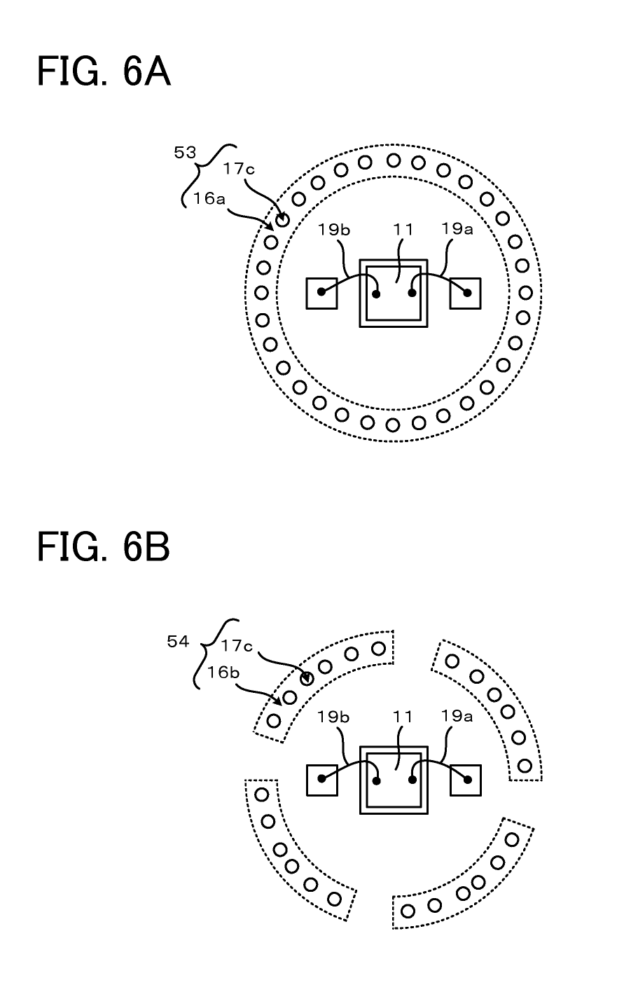

Although the opening portion 12a described here has a ring shape, the resin 13 and the substrate 12 are only required to have larger adhesion power than the contractile force F1, and the opening portion 12a may have any other shapes than the ring shape. FIGS. 5A and 5B and FIGS. 6A and 6B are plan views showing another opening portion.

As shown in FIG. 5A, each of opening portions 51 has an arc shape. The opening portion 51 partition the ring into four arcs. The arc-shaped opening portions 17b are formed on the substrate 17 so that the opening portion 17a is partitioned into the four arcs. The arc-shaped opening portions 16b are formed on the substrate 16 so that the opening portion 16a is partitioned into four arcs.

The opening portions 16b are larger than the opening portions 17b. The partition number of the opening portion 16a is not limited in particular. The arc-shaped opening portions 51 enable it to form each of the substrates 16, with just one substrate. The arc-shaped opening portions 51 advantageously make it easy to align the substrates 16, 17 in the manufacturing process.

As shown in FIG. 5B, opening portions 52 are circular. The circular opening portions 52 are disposed on a circumference. The circular opening portions 17c are formed on the substrate 17. The circular opening portions 16c are formed on the substrate 16. The opening portions 16c are larger than the opening portions 17c.

The number of the opening portions 52 is not limited in particular. The circular opening portions 52 enable it to form each of the substrates 16 and 17 with just one substrate. The circular opening portions 52 advantageously make it easy to align the substrates 16 and 17 in the manufacturing process.

As shown in FIG. 6A, an opening portion 53 is formed by combining the opening portion 12a and the opening portions 52. The circular opening portions 17c are formed on the substrate 17. The circular opening portion 16a is formed on the substrate 16.

As shown in FIG. 6B, each of opening portions 54 is formed by combining the opening portion 51 and the opening portion 52. The circular opening portions 17c are formed on the substrate 17. The arc-shaped opening portions 16b are formed on the substrate 16 so that the opening portion 16a is partitioned into four arcs.

Any other shapes than the shapes of the opening portions 51, 52, 53, 54 shown in FIGS. 5A to 6B are available. Alternatively, opening portions may be concentrically arranged on two circumferences of the substrate.

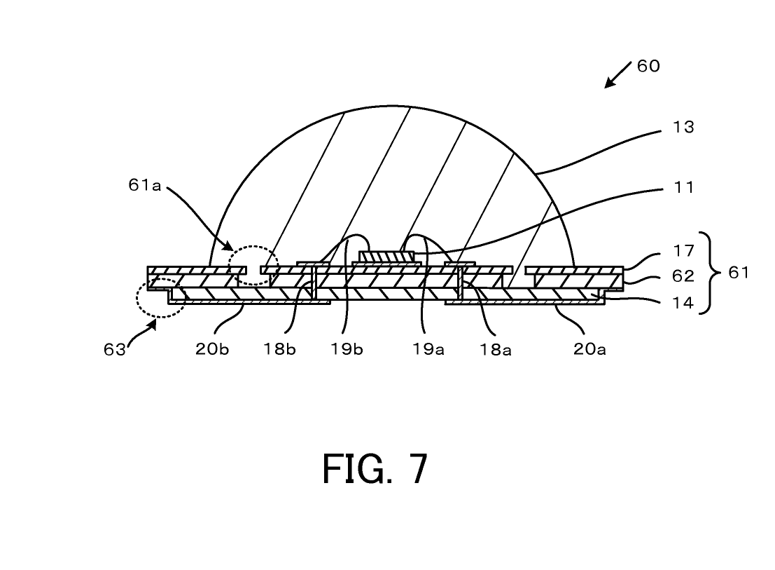

Although the substrate 12 includes the substrates 14, 15, 16, 17, it is sufficient that the substrate 12 includes at least three substrates. FIG. 7 is a sectional view showing a semiconductor light-emitting device with a substrate including three substrates.

As shown in FIG. 7, a semiconductor light-emitting device 60 includes a substrate 61 which is a stacked substrate where three substrate 14, 62, 17 are stacked in order. The substrate 62 is an intermediate substrate just below the top substrate 17, and also an intermediate substrate just above the bottom substrate 14. The substrate 62 includes a ring-shaped opening portion (a second opening portion) in the same way as the substrate 16 shown in FIGS. 1A and 1B. Edges of the opening portion 17a of the substrate 17 protrude like a visor over the opening portion of the substrate 62 toward a center line of the opening portion 17a.

An opening portion 61a is made up of an upper surface of the substrate 14 exposed to the opening portion of the substrate 62, inside walls of the opening portion of the substrate 62, and edges of the opening portion 17a protruding like a visor over the opening portion 16a. As a result, the opening portion 61a has a lower portion and an upper portion narrower than the lower portion.

The substrate 14 is smaller than the substrate 62 in size. An edge of the substrate 14 and an outermost edge of the substrate 62 make up a level difference 63. The semiconductor light-emitting device 60 advantageously enables it to thin the substrate 61.

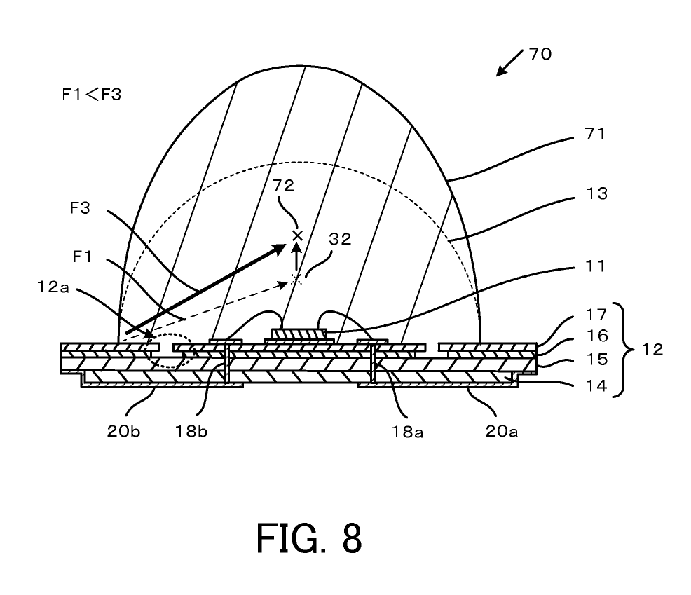

Although the dome-shaped resin 13 has the semispherical shape, the dome-shaped resin 13 may have any other shapes, e.g., a convex lens shape. FIG. 8 is a sectional view showing a semiconductor light-emitting device including a resin of a convex lens shape.

As shown in FIG. 8, a semiconductor light-emitting device 70 has a resin 71 as a convex lens. Since the resin 71 is larger than the semispherical resin 13 in size, a gravity center 72 of the resin 71 is more distant from the substrate 12 than the gravity center 32 of the resin 13.

The resin 71 and the substrate 12, which have once gone through thermal expansion due to heat of the semiconductor light-emitting element 11, contract when cooled. At that time, a contractile force F3 is generated, which detaches the resin 17 from the substrate 12. The contractile force F3 is larger than the contractile force F1 of the resin 13 shown in FIG. 2A.

The semiconductor light-emitting device 70 does not cause the resin 71 to be detached from the substrate 12 in the outer circumference thereof. The semiconductor light-emitting device 70 demonstrates that the opening portion 12a used as an anchor gives remaining adhesion power between the resin 71 and the substrate 12 to the semiconductor light-emitting device 70.

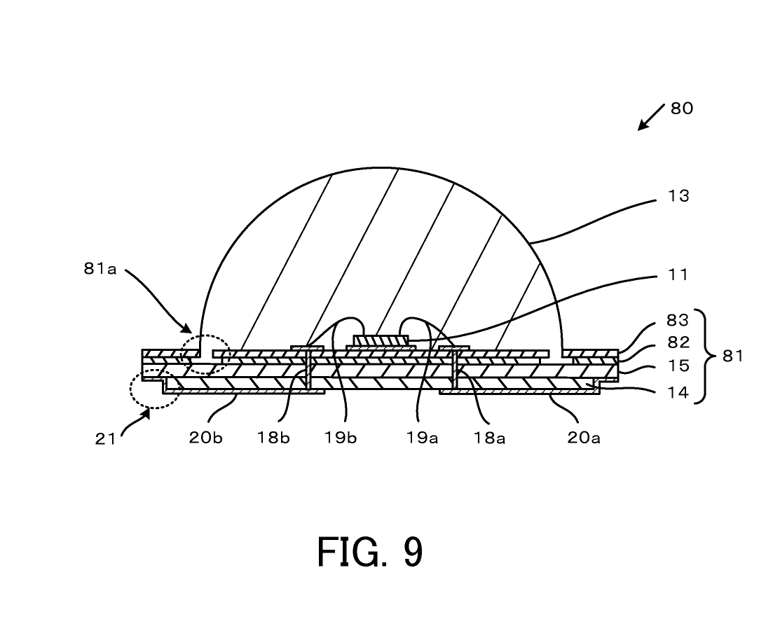

When the resin contracts, the power for tearing the resin from the substrate in an edge portion of the resin distant from the gravity center is larger than in the central portion. An opening portion operable as an anchor may be provided to a position on the substrate such that the position makes the outermost edge of the opening portion coincide with the lateral surface of the resin. FIG. 9 is a sectional view showing a semiconductor light-emitting device having an outermost edge of the opening portion, the outermost edge designed to coincide with the lateral surface of the resin.

As shown in FIG. 9, a semiconductor light-emitting device 80 includes a substrate 81 which is a stacked substrate where four substrates 14, 15, 82, 83 are stacked in order. The substrate 83 has an opening portion which has an outer sidewall in contact with the edge of the resin 13. The substrate 82 has an opening portion, the width of opening portion of the substrate 82 being larger than the width of opening portion of the substrate 83.

Edges of the opening portion of the substrate 83 protrude like a visor over the opening portion of the substrate 82 toward a center line of the opening portion of the substrate 82. An opening portion 81a is made up of an upper surface of the substrate 15 exposed to the opening portion of the substrate 82, inside walls of the opening portion of the substrate 82, and the edges of the opening portion of the substrate 83 protruding like a visor over the opening portion of the substrate 82. As a result, the opening portion 81a has a lower portion and an upper portion narrower than the lower portion.

The semiconductor light-emitting device 80 does not cause the resin 13 to be detached from the substrate 81 in the outer circumference thereof. The semiconductor light-emitting device 80 demonstrates that the opening portion 81a used as an anchor gives remaining adhesion power between the resin 13 and the substrate 81 to the semiconductor light-emitting device 80.

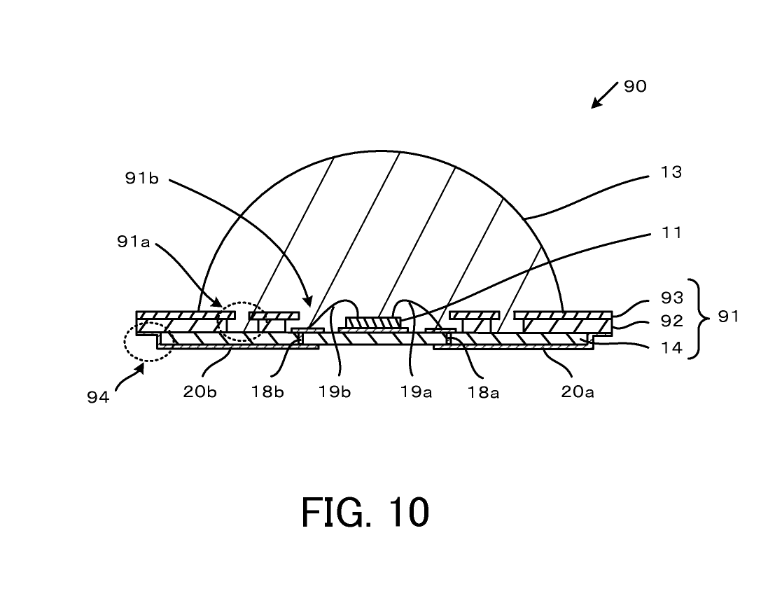

An opening portion shown in FIG. 2B may be provided in the center of a substrate of a semiconductor light-emitting device. The opening portion shown in FIG. 2B has a lower portion and an upper portion narrower than the lower portion. FIG. 10 is a sectional view showing a semiconductor light-emitting device having opening portions in an outer circumference and a central portion of a substrate. Each of the opening portions has an upper portion and a lower portion, the upper portion being narrower than the lower portion.

As shown in FIG. 10, a semiconductor light-emitting device 90 has a substrate 91 which is a stacked substrate where three substrates 14, 92, 93 are staked in order. The substrate 93 has a circular opening portion in the central portion thereof and a ring-shaped opening portion (a first opening portion) in an outer circumference thereof. The substrate 92 has a circular opening portion in the central portion thereof and a ring-shaped opening portion (a second opening portion) in an outer circumference thereof. The width of the circular opening portion of the substrate 92 is larger than the width of the circular opening portion of the substrate 93. The substrate 14 is smaller than the substrate 92 in size. A level difference 94 is made up of the edge of the substrate 14 and an outer portion of the substrate 92, the outer portion being outside the substrate 14.

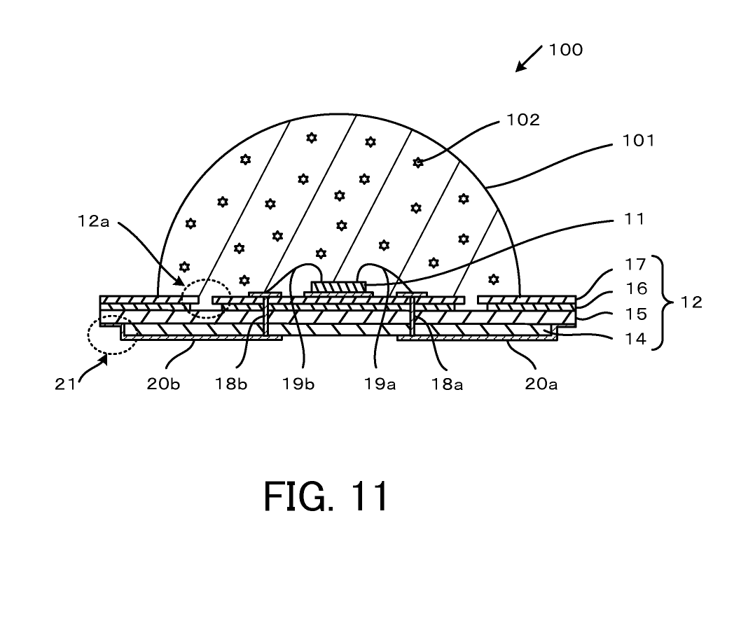

Although the fluorescent material has been described as to be provided on the upper surface of the semiconductor light-emitting element 11, the fluorescent material may be contained in resin. FIG. 11 is a sectional view showing a semiconductor light-emitting device onto which a resin containing a fluorescent material has been applied.

As shown in FIG. 11, a semiconductor light-emitting device 100 has a dome-shaped resin 101 containing a fluorescent material 102. The dome-shaped resin 101 covers the semiconductor light-emitting element 11, and fills the opening portion 12a.

The fluorescent material 102 is an yttrium aluminum garnet (YAG) fluorescent material, for example, which absorbs blue light to emit yellow light. The YAG fluorescent material is described by the following general formula as:

(RE₁₋ₓSmₓ)₃(Al_{y}Ga_{1-y})₅O₁₂:Ce, provided that 0≦x<1,0≦y≦1, and RE denotes at least one element selected from Y and Gd.

The resin 101 is a silicone resin that is transparent to blue light and yellow light, for example. The resin 101 contains the fluorescent material 102 by approximately 40 wt % to approximately 50 wt %.

The fluorescent material 102 is not limited to a YAG fluorescent material. The fluorescent material 102a may be a red fluorescent material of SiAlON or a green fluorescent material of SiAlON. In that case, a semiconductor light-emitting device that emits light with which blue light and red or green light are mixed is obtained.

Although the resin 13 has been described as silicone resin, the resin 13 may be epoxy resin. The thermal expansion coefficient of an epoxy resin is 4.5×10⁻⁵/K to 6.5×10⁻⁵/K, for example.

Although the semiconductor light-emitting element 11 has been described as a blue-light-emitting element that emits blue light with a peak wavelength of 400 nm to 480 nm, the semiconductor light-emitting element 11 may be a near-ultraviolet-light emitting element that emits near-ultraviolet light with a peak wavelength of 300 nm to 400 nm. Examples of the near-ultraviolet-light emitting element include an AlGaN-based nitride semiconductor light-emitting element. When the semiconductor light-emitting element 11 is a near-ultraviolet-light emitting element, the semiconductor light-emitting element 11 employs an RGB fluorescent material.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor light-emitting device, comprising:
a substrate configured to have an opening portion, the opening portion including a lower portion and an upper portion narrower than the lower portion;
a semiconductor light-emitting element placed in a central portion of the substrate; and
a transparent resin covering the semiconductor light-emitting element and being provided to the opening portion.

2. The device according to claim 1, wherein
the substrate includes at least three substrates, the at least three substrate including a first substrate, a second substrate, and a third substrate, the first substrate having a first opening portion, the second substrate just below the first substrate having a second opening portion, the width of the second opening portion larger than the width of the first opening portion, the first opening portion and the second opening portion forming the opening portion in the substrate.

3. The device according to claim 2, further comprising
a via passing through the substrate and provided between the semiconductor light-emitting element and the opening portion, first end of the via electrically connected to the semiconductor light-emitting element, second end of the via electrically connected to an electrode, the electrode being provided to the third substrate.

4. The device according to claim 3, wherein
the third substrate is smaller than the second substrate just above the third substrate, and the electrode extends from the second end of the via to the substrate just above the third substrate.

5. The device according to claim 2, wherein
both the first and second opening portions have one of a ring shape, an arc shape, and a circular shape.

6. The device according to claim 2, wherein
the first opening portion has a circular shape, and the second opening portion has a ring shape or an arc shape.

7. The device according to claim 1, wherein
the semiconductor light-emitting element emits first light having a first peak wavelength in a range of 400 nm to 480 nm or in a near-ultraviolet range; and
a fluorescent material is provided between the semiconductor light-emitting element and the resin, the fluorescent material absorbing the first light to emit second light having a second peak wavelength longer than the first peak wavelength.

8. The device according to claim 1, wherein
the semiconductor light-emitting element emits third light having a third peak wavelength in a range of 400 nm to 480 nm or in a near-ultraviolet range; and
the resin includes a fluorescent material, the fluorescent material absorbing the third light to emit fourth light having a fourth peak wavelength longer than the third peak wavelength.

9. The device according to claim 1, wherein
the resin has a semispherical shape or a convex lens shape.

10. The device according to claim 1, wherein
the semiconductor light-emitting element includes nitride semiconductors.

11. The device according to claim 1, wherein
the resin is silicone resin or epoxy resin.

12. The device according to claim 1, wherein
the fluorescent material is an yttrium aluminum garnet fluorescent material.

13. A semiconductor light-emitting device, comprising:
a substrate configured to have an opening portion, the opening portion includes a lower portion and an upper portion narrower than the lower portion, the substrate including at least three substrates, the at least three substrate including a first substrate, a second substrate, and a third substrate, the first substrate having a first opening portion, the second substrate just below the first substrate having a second opening portion, the width of the second opening portion being larger than the width of the first opening portion, both the first and second opening portion forming the opening portion in the substrate;
a semiconductor light-emitting element placed in a central portion of the substrate; and
a transparent resin covering the semiconductor light-emitting element and being provided to the opening portion.

14. The device according to claim 13, further comprising
a via passing through the substrate and provided between the semiconductor light-emitting element and the opening portion, first end of the via electrically connected to the semiconductor light-emitting element, second end of the via electrically connected to an electrode, the electrode being provided to the third substrate.

15. The device according to claim 14, wherein
the third substrate is smaller than the second substrate just above the third substrate, and the electrode extends from the first end of the via to the second substrate.

16. The device according to claim 13, wherein
both the first and second opening portions have one of a ring shape, an arc shape, or a circular shape.

17. The device according to claim 13, wherein
the first opening portion has a circular shape, and the second opening portion has a ring shape or an arc shape.

18. The device according to claim 13, wherein
the semiconductor light-emitting element emits first light having a first peak wavelength in a range of 400 nm to 480 nm or in a near-ultraviolet range; and
a fluorescent material is provided between the semiconductor light-emitting element and the resin, the fluorescent material absorbing the first light to emit second light having a second peak wavelength longer than the first peak wavelength.

19. The device according to claim 13, wherein
the semiconductor light-emitting element emits third light having a third peak wavelength in a range of 400 nm to 480 nm or in a near-ultraviolet range; and
the resin includes a fluorescent material, the fluorescent material absorbing the third light to emit fourth light having a fourth peak wavelength longer than the third peak wavelength.

20. The device according to claim 13, wherein
the resin has a semispherical shape or a convex lens shape.
